(19) United States
(12) Patent Application Publication
(10) Pub. No.: US 2008/0293209 A1
(43) Pub. Date: Nov. 27, 2008

(54) Thin film multiplayer ceramic capacitor devices and manufacture thereof

(76) Inventor: Michael S. Radall, Simpsonville, SC (US)

Correspondence Address: NEXSEN PRUET, LLC, P.O. BOX 10648, GREENVILLE, SC, 29603, US

(21) Appl. No.: 11/805,018

(22) Filed: May 22, 2007

(51) Int. Cl. H01L 21/62

(52) U.S. Cl. 438/381; 257/E21.008; 257/E21.011

(57) ABSTRACT

A process for forming a capacitor including the steps of:
forming a conductive layer on a capacitor precursor wherein the capacitor precursor has a substrate, a first conductor in electrical contact with the substrate; a second conductor; and a dielectric between the first conductor and the second conductor and also between the second conductor and the substrate;
applying a mask to the conductive layer wherein the mask projects to the first conductor and the second conductor;
etching the conductive layer which is void of mask to remove a portion of conductive layer;
adding a dielectric to an area of removed conductive layer;
removing the mask;
sintering the dielectric;
smoothing a surface of the dielectric and the conductive layer remaining after the etching; and
forming an terminal conductive layer in electrical contact with the second conductor and separated from the first conductor by dielectric.

### BACKGROUND OF THE INVENTION

The present invention is related to multilayer ceramic capacitors and methods of manufacturing them. More particularly, the present invention is related to thin film multilayer capacitors with a large number of thin layers, relative to the prior art, and to a method of manufacturing same.

Capacitors are utilized in virtually all electronic components in one form or another. They are a passive component used to store charge for rapid release or as a decoupling devices to reduce noise in a power trace. The use of multilayer ceramic capacitors in electronic circuitry is widely known and further discussion herein is not necessary.

Multilayer ceramic capacitors are typically manufactured in a repeated process of alternately overlaying patterned ceramic layers with patterned electrode layers and laminating the layers together with pressure and heat. The ceramic is sintered either between subsequent layers or in a single sintering. As is well known the sequential steps of layering ceramic precursor, sintering to form ceramic, electrode layering, additional ceramic precursor layering, etc. is difficult to achieve without some level of distortion in the layer thickness at each level. The distortion, though minor at each individual layer, is additive. After multiple layers are combined the minor distortions become problematic leading to limits in the total number of layers which can be used or the quality of the resulting capacitor.

The present application provides an improved process of capacitor formation which substantially eliminates distortions and allows a very large number of layers to be formed.

### SUMMARY OF THE INVENTION

It is an object of the present invention to provide a multilayer ceramic capacitor comprising a large number of layers.

It is another object of the present invention to provide a process for forming a multilayer ceramic capacitor with virtually no layer distortion at each layer.

A particular feature of the present invention is the ability to form a capacitor with very thin electrode and dielectric layers thereby increasing capacitance as a function of volume.

These and other advantages, as will be realized, are provided in a process for forming a capacitor. The process includes the steps of:
forming a conductive layer on a capacitor precursor wherein the capacitor precursor has a substrate, a first conductor in electrical contact with the substrate; a second conductor; and a dielectric between the first conductor and the second conductor and also between the second conductor and the substrate;
applying a mask to the conductive layer wherein the mask projects to the first conductor and the second conductor;
etching the conductive layer which is void of mask to remove a portion of conductive layer;
adding a dielectric to an area of removed conductive layer;
removing the mask;
sintering the dielectric;
smoothing a surface of the dielectric and the conductive layer remaining after the etching; and
forming an terminal conductive layer in electrical contact with the second conductor and separated from the first conductor by dielectric.

Yet another embodiment is provided in a method for forming a capacitor. The method includes:
providing a substrate;
forming a multiplicity of first conductors in electrical contact with the substrate;
forming a dielectric layer between the multiplicity of first conductors;
forming a conductive layer on the dielectric layer;
applying a mask to the conductive layer wherein the mask projects to the first conductor and a location of a second conductor wherein the first conductor and the second conductor are in parallel alternating relationship;
etching the conductive layer in areas not covered by the mask forming voids;
filling the voids with dielectric;
sintering the dielectric;
removing the mask; and
smoothing a surface formed by the dielectric and the conductive layer.

### BRIEF DESCRIPTION OF DRAWINGS

FIGS. 1-8 schematically illustrate sequential steps in the process of the present invention.

FIG. 9 schematically illustrates a finished capacitor of the present invention.

FIG. 10 schematically illustrates an embodiment of the present invention in top partial cut-away view.

FIG. 11 schematically illustrates an embodiment of the present invention in top view.

FIG. 12 is a top schematic view of an embodiment of the present invention.

FIG. 13 is a cross-sectional view taken along line 13-13 of FIG. 12.

FIG. 14 schematically illustrates CMP.

### DETAILED DESCRIPTION

The invention will be described with particular reference to the figures. The figures are non-limiting and are provided for the purpose of describing and illustrating the invention. In the various figures similar elements are numbered accordingly.

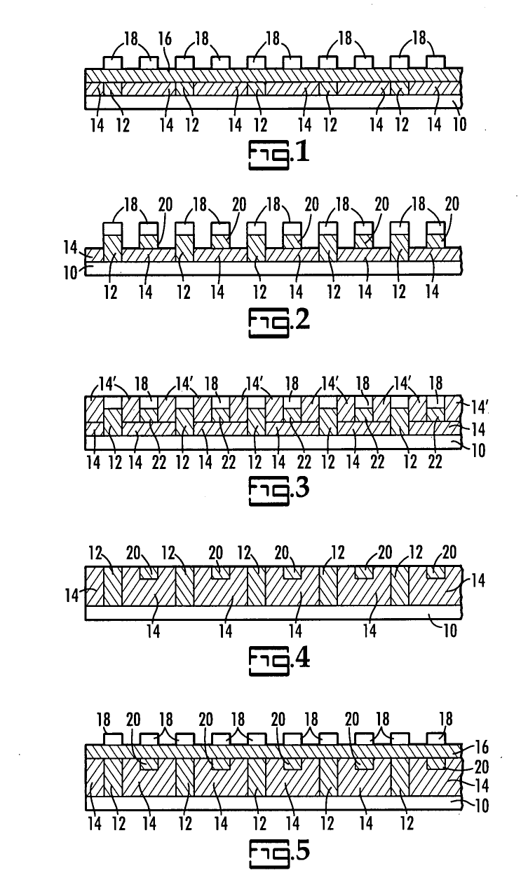

A thin film capacitor, and method of manufacturing a thin film capacitor, is provided herein. The process will be described with particular reference to the cross-sectional schematic views of FIGS. 1-7 illustrating the order in which layers are applied. It is understood that the cross-sectional view does not illustrate the width or length of the layers neither of which is limited by the invention.

FIG. 1 illustrates an initial formation step for the capacitor. A substrate, 10, forms the base upon which the capacitor will be assembled. The substrate is preferably a conductive layer which will form an external electrode of the finished capacitor. Particularly preferable materials for the substrate include copper, nickel, silver, platinum, palladium, gold, niobium, niobium oxide, tantalum, titanium and combinations and alloys thereof or conductive ceramic materials. First conductors, 12, are applied to the surface of the substrate with dielectric, 14, between the first conductors. The areas of first conductor may be a rectangular section over all or a portion of the length of the substrate or it may be in discrete areas such as in a grid pattern. The separation of the first conductors is at least approximately 1.5 times the distance of the plate separation desired in the finished capacitor as will be realized upon further discussion. The first conductor is in electrical contact with the substrate. The surface of the first conductor and dielectric is preferably smoothed by chemical mechanical planarization (CMP), or the like, to insure a smooth continuous surface parallel to the surface of the substrate prior to further processing. A continuous conductor layer, 16, is applied over the surface of the first conductor and previously applied dielectric. As would be realized the continuous conductor layer is in electrical contact with each first conductor. A mask, 18, is applied over the continuous conductor layer wherein the mask is a projection of the two electrode layers representing the plates of opposing polarity in the final capacitor. In the present example the first conductor may be the anodic conductor and the second conductor may be the cathodic conductor of the capacitor. After forming the mask the continuous electrode layer is etched.

The term projection, or to project, as used herein refers to a shape which reproduces the shape of the object there-under.

Referring now to FIG. 2 the continuous electrode layer is illustrated after etching resulting in a thicker first conductor, 12, and a second conductor, 20, in alternating arrangement. Both the first conductor and second conductor are a projection of the mask. The dielectric, 14, is between the second conductor substrate. The entirety of the first conductor is in electrical contact with the substrate whereas the second conductor is separated from the substrate by dielectric.

Referring now to FIG. 3, the margins between the islands formed by electrodes and mask are filled with dielectric, 14′. The dielectric is illustrated as a distinct layer but in fact this becomes a continuation of the original dielectric layer, 14, after firing and is distinguished here for clarity. After application of the dielectric in the margins the mask is removed and the dielectric may be sintered. The surface is then planarized by CMP resulting in the structure illustrated in FIG. 4.

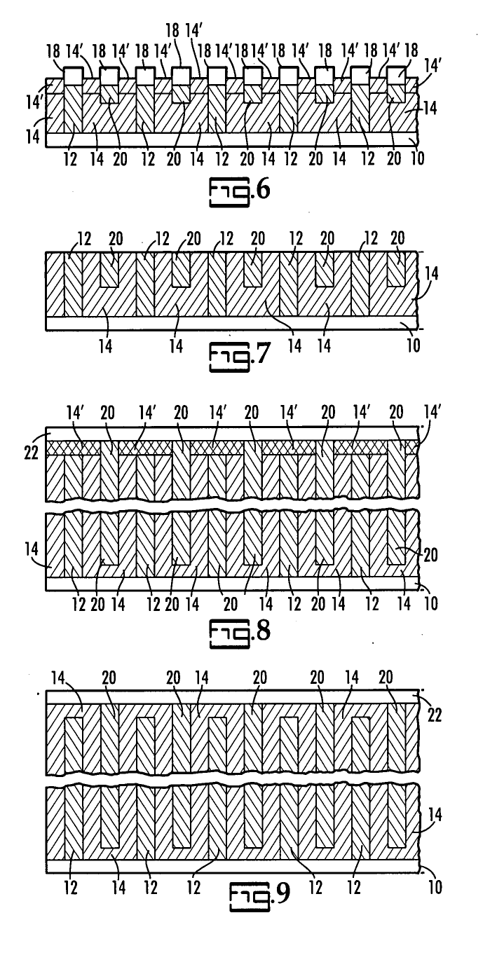

With reference to FIG. 5, a continuous electrode layer, 16, is applied over the surface. As would be realized the continuous electrode layer is in electrical contact with both the first conductor and the second conductor. A mask, 18, is applied over the continuous electrode layer wherein the projection of the mask is coincident with the first conductor and second conductor. The electrode area not protected by the mask is etched and dielectric is applied to the margins between the island of electrode and mask as described above and illustrated in FIG. 6. The mask is removed, the dielectric sintered, and the surface preferably planed by CMP resulting in the structure illustrated in FIG. 7, wherein the length of each conductor, measured from the substrate, is increased by approximately the layer thickness of the continuous electrode layer. While described as a continuous electrode layer over the entire surface this is to capture a preferred embodiment which is greatly simplified over partial layers being applied. Partial layers can be applied but this increases manufacturing complexity and is therefore not preferred.

The process of applying a continuous electrode, applying a mask, etching the continuous electrode in those regions void of a mask, inserting dielectric in the margins vacated by the etching, firing and surface planing by CMP are repeated the number of times necessary to form the capacitor thickness desired as measured perpendicular to the substrate. If so desired, the resulting device may also be manufactured on a removable substrate.

It is preferred that the ceramic be fired after each application thereof. Multiple ceramic layers can be applied prior to firing. The ceramic can be sintered after several layers, for example three, are formed to minimize the number of manufacturing steps while still providing adequate product quality.

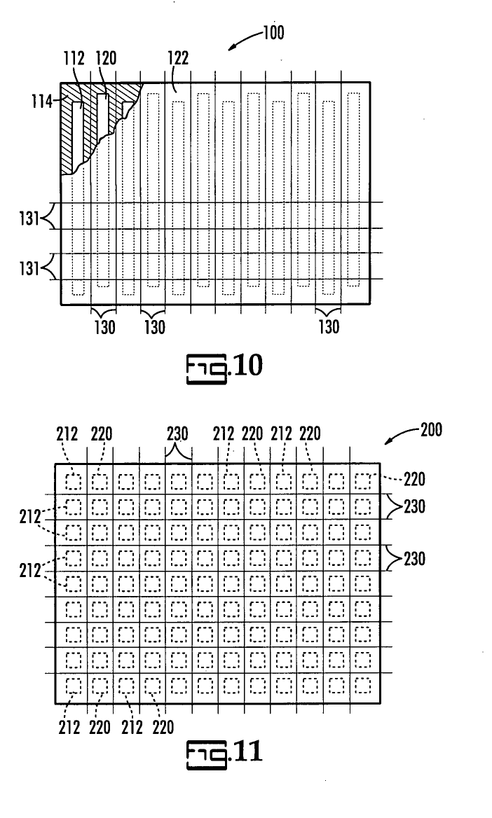

When a sufficient number of layers have been applied a termination is applied to form the terminal of opposing polarity to the substrate. To accomplish this dielectric is applied between the first conductor and the termination. As illustrated in FIG. 8, a dielectric, 14′, is applied between the second conductors, 20, and covering the first conductors, 12. The ceramic is sintered and a terminal continuous conductive layer, 22, is formed thereon in electrical contact with the second conductors but separated from the first conductors by dielectric. The continuous conductive layer forms the external termination for the capacitor with polarity which is opposite that of the substrate, 10.

A finished capacitor is illustrated schematically in cross-sectional view in FIG. 9. The number of alternating conducting layers can be very high, such as much higher than 400 layers. The number of alternating layers can exceed 1000 layers with about 10,000 layers being suitable. Above about 1,000 layers the yield efficiency decreases since a defect renders a large amount of material scrap, however, when capabilities are utilized to dice the capacitor selectively to cull regions containing defects the number of layers is essentially limitless from a technology perspective and is only limited by manufacturing equipment feasibility.

The thickness of the conductive layers and dielectric layers is small relative to the prior art. Conductor thicknesses, measured parallel to the substrate, of no more than 3 μm are easily prepared. More preferably the layer thickness can be no more than 1 μm. A layer thickness of at least 0.010 μm to 0.70 μm is most preferred. Furthermore, the process allows for the manufacture of a capacitor with a large number of very thin conductors and dielectric. The capacitor can then be diced to form a large number of small capacitors if desired.

The capacitor can be used as a single device or the capacitor can be separated into smaller capacitors in a process referred to as singulation which will be more fully described herein.

A schematic partial-cutaway top view of a capacitor of the present invention is generally illustrated at 100 of FIG. 10. In FIG. 10, the first conductor, 112, and second conductor, 120, are in parallel alternating relationship with dielectric, 114, there between. The first conductor is in electrical contact with the substrate (not shown) on the opposite side and the second conductor is in electrical contact with the continuous conductive layer, 122. The capacitor can be used as illustrated as a polar capacitor with opposing faces having opposing polarity. Alternatively, the capacitors can be diced along primary dice lines, 130, yielding a multiplicity of elongated polar capacitors. The capacitor can be further separated by Cutting along secondary dice lines, 131, which are not parallel to the conductors or the primary dice lines to form smaller polar capacitors.

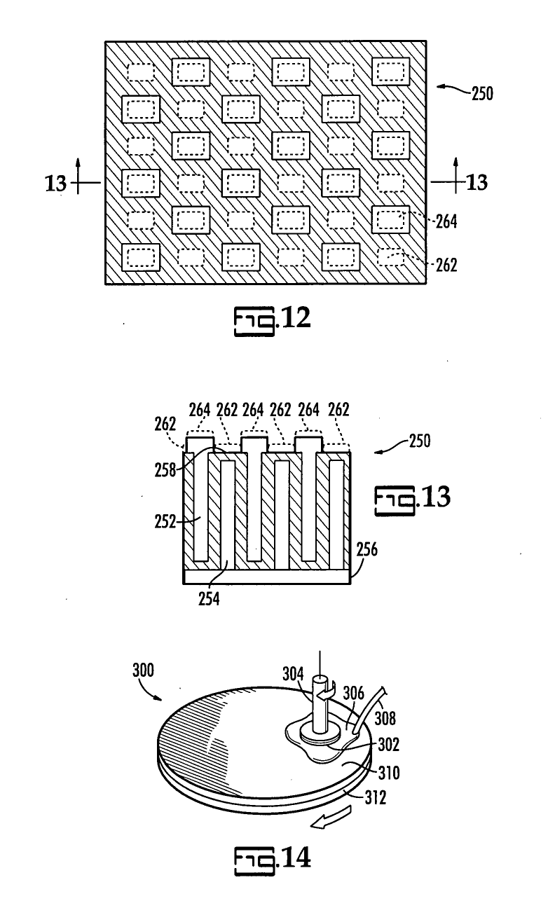

A particularly preferred embodiment will be described with reference to FIG. 11. In FIG. 11, the capacitor generally represented in top schematic view at 200, comprises a continuous conductive layer, 220. Illustrated in dotted line are the first conductors, 212, and second conductors, 220, in alternating fashion. The second conductors, 220, are in electrical contact with the continuous conductive layer and the first conductors, 212, are in electrical contact with the substrate on the opposite side of the continuous conductive layer which is not shown. In this embodiment each conductor is a capacitive couple with each adjacent conductor. The capacitor can be separated into discrete capacitors by cutting along select dice lines, 230. The dice lines illustrated would provide a multiplicity of capacitors with two parallel conductors, one being the first conductor arbitrarily designated either positive or negative polarity and the other being the second conductor arbitrarily designated either positive or negative polarity. The capacitor could be diced in an alternate pattern to provide a capacitor with three conductors, four conductors, etc. It is most preferred to have an even number of conductors with half being in electrical contact with each opposing face. An uneven number of conductors can be used in some instances.

An embodiment of the invention is illustrated in top schematic view in FIG. 12 and in cross-sectional schematic view in FIG. 13 taken along line 13-13 of FIG. 12. The capacitor, generally represented at 250, comprises first conductors, 252, and second conductors, 254, with a dielectric, 258, there between. As described herein the second conductors are in electrical contact with a substrate, 256. A continuous electrode layer, shown in dotted line at 260 of FIG. 13, has been removed by etching. An area which is preferably larger than the second electrode is protected by a mask, 262, which has been removed but the location has been shown by clotted lines, 264. A capacitor which is attachable by a ball grid array is provided thereby. The substrate, 256, can also be masked and etched to provide a similar pattern on the opposing side. The etching can be done prior to or after dicing.

The conductive and dielectric materials are not particularly limited herein.

Exemplary conductive materials include any conductive metal with silver, nickel, copper, gold, platinum, palladium, aluminum, alloys of two or more of any of these materials and the like being preferred. More preferred are alloys of silver/palladium, nickel, copper, silver, platinum and alloys of gold/platinum/palladium.

Exemplary dielectrics include barium titanates, modified barium titanates, relaxor dielectrics and class 1, 2 or 3 ceramic dielectrics. Most preferred are modified barium titanates and relaxors.

The method of cutting along dice lines is not particularly limiting herein with the exception that it is preferable to utilize a method which is accurate and which has a minimal kerf and minimal error such that waste is reduced. Blade dicing, saw dicing, water jet, laser cutting, rotary cutting, shearing, die punching or other methods known in the art are exemplary.

Chemical mechanical planarization, also referred to as chemical-mechanical polishing, (CMP) is a widely known technique for planarizing the top surface of an in-process semiconductor wafer. In general, the process involves the use of abrasive, corrosive slurry to physically and chemically remove topographic features on the surface of a work piece. The process will be described generically with reference to FIG. 14. In FIG. 14, the CMP apparatus, generally represented in perspective schematic side view at 300, polishes, or abrades, the surface of an in-process capacitor, 302. The in-process capacitor is secured to a carrier, 304, which rotates as represented by the arrow thereon. The in-process capacitor is placed in contact with abrasive slurry, 306, supplied by a slurry supply line, 308, on a polishing pad, 310. The polishing pad is attached to a platen which may also be rotated, as indicated by the arrow thereon. In another embodiment the platen is fixed and the carrier traverses around the surface of the polishing pad wherein the relative motion may mimic a rotating platen. The action of the in-process capacitor rotating and the polishing pad rotating abrades the surface of the in-process capacitor thereby forming a smooth surface. The abrasive slurry is not particularly limited herein, however a typical slurry is silicon dioxide particles in a potassium hydroxide, ammonium hydroxide, or other suitable solution. CMP equipment and specialized slurries are commercially available from numerous sources.

The process has been described with particular reference to the preferred embodiments without limit thereto. One of skill in the art would realize other embodiments, alterations, and improvements which are within the scope of the invention as set forth in the claims appended hereto.

1. A process for forming a capacitor comprising the steps of:
forming a conductive layer on a capacitor precursor wherein said capacitor precursor comprises a substrate a first conductor in electrical contact with said substrate; a second conductor; and a dielectric between said first conductor and said second conductor and also between said second conductor and said substrate;
applying a mask to said conductive layer wherein said mask projects to said first conductor and said second conductor;
etching said conductive layer which is void of said mask to remove a portion of said conductive layer;
adding a dielectric to an area of said removed conductive layer;
removing said mask;
sintering said dielectric;
smoothing a surface of said dielectric and said conductive layer remaining after said etching; and
forming an terminal conductive layer in electrical contact with said second conductor and separated from said first conductor by said dielectric.

2. The process for forming a capacitor of claim 1 wherein said smoothing is by chemical mechanical planarization.

3. The process for forming a capacitor of claim 1 further comprising:
dicing said capacitor.

4. The process for forming a capacitor of claim 1 wherein said substrate is removable.

5. The process for forming a capacitor of claim 1 further comprising:
applying a second mask to said terminal conductive layer wherein said second mask projects to an area comprising said second conductor; and
etching said terminal conductive layer.

6. The method for forming a capacitor of claim 1 wherein said first conductor has a width of no more than 3 μm.

7. The method for forming a capacitor of claim 6 wherein said first conductor has a width of no more than 0.7 μm.

8. The method for forming a capacitor of claim 7 wherein said first conductor has a width of at least 0.01 μm to no more than 1 μm.

9. The method for forming a capacitor of claim 1 comprising sintering said dielectric prior to addition of an additional dielectric layer.

10. The method of forming a capacitor of claim 1 comprising forming said conductor layer at least 400 times.

11. The method of forming a capacitor of claim 1 wherein said conductive layer is continuous over the surface of said capacitor precursor.

12. A method for forming a capacitor comprising:
providing a substrate;
forming a multiplicity of first conductors in electrical contact with said substrate;
forming a dielectric layer between said multiplicity of first conductors;
forming a conductive layer on said dielectric layer;
applying a mask to said conductive layer wherein said mask projects to said first conductor and a location of a second conductor wherein said first conductor and said second conductor are in parallel alternating relationship;
etching said conductive layer in areas not covered by said mask forming voids;
filling said voids with dielectric;
sintering said dielectric;
removing said mask; and
smoothing a surface formed by said dielectric and said conductive layer.

13. The method of forming a capacitor of claim 12 comprising sintering said dielectric prior to said forming a conductive layer.

14. The method of forming a capacitor of claim 12 wherein said substrate is removable.

15. The method of forming a capacitor of claim 12 further comprising:
applying a second conductive layer;
applying a second mask projecting to said first conductor and said second conductor;
etching said second conductor;
applying said dielectric to areas of removed conductive layer; and
removing said mask.

16. The method of forming a capacitor of claim 15 further comprising smoothing a surface formed by said dielectric and said conductive layer;

17. The method for forming a capacitor of claim 16 wherein said substrate is removable.

18. The method of forming a capacitor of claim 15 comprising sintering said dielectric.

19. The method of forming a capacitor of claim 12 further comprising:
applying a finish conductive layer in electrical contact with said second conductor and separated from said conductor by dielectric.

21. The method of forming a capacitor of claim 19 further comprising masking and etching said finish conductive layer.

22. The method of forming a capacitor of claim 15 wherein said substrate is removable.
